(19) United States
(12) Patent Application Publication
(10) Pub. No.: US 2021/0040344 A1
(43) Pub. Date: Feb. 11, 2021

(54) CONDUCTIVE PASTE, CURED PRODUCT, CONDUCTIVE PATTERN, GARMENT AND STRETCHABLE PASTE

(71) Applicant: NAMICS CORPORATION, Niigata-shi, Niigata (JP)

(72) Inventor: Tomoyuki TAKAHASHI, Niigata-shi, Niigata (JP)

(73) Assignee: NAMICS CORPORATION, Niigata-shi, Niigata (JP)

(21) Appl. No.: 16/968,179

(22) PCT Filed: Jan. 16, 2019
(86) PCT No.: PCT/JP2019/001031

§ 371 Date: Aug. 7, 2020

(30) Foreign Application Priority Data
Feb. 8, 2018 (JP) 2018-021179

(51) Int. Cl. C09D 11/52; C09D 11/037; H05K 1/09; A41D 31/04; C09D 11/102; H01B 1/22

(52) U.S. Cl. CPC C09D 11/52; C09D 11/037; H05K 1/092; H05K 2201/0314; C09D 11/102; H01B 1/22; A41D 31/04

(57) ABSTRACT

An electrically conductive paste contains (A) metal-coated particles each composed of titanium oxide and a metal coating layer formed on the surface of the titanium oxide and (B) a resin. The titanium oxide has a columnar form having a particle length and a particle shorter diameter and the particle length of the titanium oxide is longer than the particle shorter diameter. Each of the metal-coated particles has a columnar form having a particle length and a particle shorter diameter and the particle length of each of the metal-coated particles is longer than the particle shorter diameter.

### TECHNICAL FIELD

The present invention relates to a conductive paste used in electrical components and electronic components, a cured product and a conductive pattern from the conductive paste, and garments including the cured product and the conductive pattern. The present invention also relates to a stretchable paste used in electrical components and electronic components.

### BACKGROUND ART

Conductive elastomers obtained by adding conductive materials such as metal powders, carbon fibers, carbon powders and graphite powders to matrixes such as polyurethanes and silicone rubbers are used as materials for electronic components such as connectors, switches and sensors. As such a conductive elastomer, Patent Document 1 describes a conductive elastomer composition which includes a silicone rubber as a matrix, and conductive fibers formed by coating the surface of inorganic fibers with silver.

As conductive fibers formed by coating the surface of inorganic fibers with a metal, Patent Document 2 describes conductive fibers in which the surface of a fibrous material is coated with a mixture of a noble metal and one, or two or more kinds of oxides thereof.

Patent Document 3 describes a conductive composition which includes potassium titanate fibers having a layer, deposited on the surface thereof, of at least one metal selected from the group consisting of Pt, Au, Ru, Rh, Pd, Ni, Co, Cu, Cr, Sn and Ag.

Patent Document 4 describes a metal-coated titanate which includes a titanate crystal with a specific reduced form, and at least one metal selected from the group consisting of Ni, Cu, Ag, Au and Pd attached to the surface of the crystal.

Patent Document 5 describes a stretchable conductive film for textiles. Specifically, Patent Document 5 describes a stretchable conductive film which includes a stretchable conductive layer having elasticity, and a hot melt adhesive layer disposed on one side of the stretchable conductive layer. Further, it is described that the stretchable conductive layer is formed of a conductive composition including an elastomer and a conductive filler filled in the elastomer.

Patent Document 6 describes a stretchable conductive circuit. Specifically, Patent Document 6 describes a stretchable conductive circuit including an elastomer sheet and a conductive fibrous material. An adhesive layer is formed on the surface of an elastomer sheet so as to correspond to a predetermined pattern of wiring regions. A conductive fibrous material have a predetermined diameter and a predetermined length. The conductive fibers are attached to the adhesive layer and in contact with each other and electrically conductive along the wiring regions. Further, Patent Document 6 describes that when the elastomer sheet is stretched and contracted or is bent, the conductive fibers move relative to one another while still being electrically conductive to one another to maintain the electrical continuity in the wiring regions.

Patent Document 7 describes conductive titanium oxide having a conductive coating on the particle surface.

Patent Document 8 discloses a method for producing metal-coated metal oxide microparticles, and describes that a metal salt is reduced to form a metal coating layer. Further, Patent Document 8 describes that rutile titanium oxide microparticles are used as the metal oxide microparticles.

Patent Document 1: JP H5-194856 A

Patent Document 2: JP S63-85171 A

Patent Document 3: JP S57-103204 A

Patent Document 4: JP S58-20722 A

Patent Document 5: JP 2017-101124 A

Patent Document 6: WO 2015/174505

Patent Document 7: WO 2007/102490

Patent Document 8: JP 2012-116699 A 25

### DISCLOSURE OF THE INVENTION

In the manufacturing of electrical components and electronic components, conductive parts such as wirings and electrodes (collectively written simply as “wirings”) of electrical circuits and/or electronic circuits may be formed by printing a conductive paste into predetermined shapes followed by firing. For example, the conductive particles contained in the conductive paste are typically spherical metal particles or flake particles formed by processing spherical metal particles.

In recent years, attempts have been made to form wirings of electrical circuits and/or electronic circuits on the surface of flexible and/or stretchable materials. When a wiring is formed on such a material, there is a risk that the wiring will be disconnected by the bending and/or the stretching of the material.

It is therefore an object of the present invention to provide a conductive paste capable of forming a wiring of an electrical circuit and/or an electronic circuit that has a low possibility of disconnection. Specifically, an object of the present invention is to provide a conductive paste capable of forming a wiring of an electrical circuit and/or an electronic circuit having a low possibility of disconnection and a relatively small change in electric resistance, on a surface of a flexible and/or a stretchable material.

Another object of the present invention is to provide a cured product and a conductive pattern, which may be used as a wiring of an electrical circuit and/or an electronic circuit having a low possibility of disconnection. A further object of the present invention is to provide a garment including a wiring of an electrical circuit and/or an electronic circuit having a low possibility of disconnection.

A still further object of the present invention is to provide a stretchable paste that may be used to form stretchable electrodes on electrical components and electronic components.

To solve the above problems, the present invention has the following configurations.

(Configuration 1)

Configuration 1 of the present invention is a conductive paste comprising (A) metal-coated particles having a metal coating layer on the surface of titanium oxide, and (B) a resin, wherein the titanium oxide has a columnar shape having a particle length and a particle shorter diameter, the particle length of the titanium oxide is longer than the particle shorter diameter, the metal-coated particles have a columnar shape having a particle length and a particle shorter diameter, and the particle length of the metal-coated particles is longer than the particle shorter diameter.

The conductive paste obtained according to Configuration 1 of the present invention can form a wiring of an electrical circuit and/or an electronic circuit having a low possibility of disconnection. Specifically, the conductive paste obtained according to Configuration 1 of the present invention can form a wiring of an electrical circuit and/or an electronic circuit having a low possibility of disconnection and a relatively small change in electric resistance, on a surface of a flexible and/or a stretchable material.

(Configuration 2)

Configuration 2 of the present invention is the conductive paste of Configuration 1, wherein the metal coating layer of (A) the metal-coated particles comprises at least one selected from the group consisting of Ag, Au, Cu, Ni, Pd, Pt, Sn and Pb.

The conductive paste according to Configuration 2 of the present invention can form a wiring of an electrical circuit and/or an electronic circuit having a low electric resistance by virtue of the metal coating layer containing the specified metal.

(Configuration 3)

Configuration 3 of the present invention is the conductive paste of Configuration 1 or 2, wherein the particle length of (A) the metal-coated particles is 1.5 to 30 μm.

The conductive paste obtained according to Configuration 3 of the present invention can reliably form a wiring of an electrical circuit and/or an electronic circuit having a low possibility of disconnection by virtue of the use of the metal-coated particles having the specified particle length. Specifically, the conductive paste obtained according to Configuration 3 of the present invention can reliably form a wiring of an electrical circuit and/or an electronic circuit having a low possibility of disconnection, on a surface of a flexible and/or a stretchable material.

(Configuration 4)

Configuration 4 of the present invention is the conductive paste of any of Configurations 1 to 3, wherein the particle shorter diameter of (A) the metal-coated particles is 0.1 to 10 μm.

The conductive paste obtained according to Configuration 4 of the present invention can more reliably form a wiring of an electrical circuit and/or an electronic circuit having a low possibility of disconnection by virtue of the use of the metal-coated particles having the specified particle shorter diameter. Specifically, the conductive paste obtained according to Configuration 4 of the present invention can more reliably form a wiring of an electrical circuit and/or an electronic circuit having a low possibility of disconnection, on a surface of a flexible and/or a stretchable material.

(Configuration 5)

Configuration 5 of the present invention is the conductive paste of any of Configurations 1 to 4, wherein the specific surface area of (A) the metal-coated particles is 0.2 to 20 m²/g.

According to Configuration 5 of the present invention, since the metal-coated particles contained in the conductive paste have the predetermined specific surface area, the conductive paste with an appropriate size for forming a wiring of an electrical circuit and/or an electronic circuit can be reliably obtained.

(Configuration 6)

Configuration 6 of the present invention is the conductive paste of any of Configurations 1 to 5, wherein the ratio of the particle length to the particle shorter diameter (particle length/particle shorter diameter) of (A) the metal-coated particles is 3 to 300. By virtue of the use of titanium oxide having the specified aspect ratio (particle length/particle shorter diameter), a wiring of an electrical circuit and/or an electronic circuit having a low possibility of disconnection can be more reliably formed on a surface of a flexible and/or a stretchable material.

(Configuration 7)

Configuration 6 of the present invention is the conductive paste of any of Configurations 1 to 6, wherein the weight ratio of the weight of the metal coating layer to the weight of the titanium oxide in (A) the metal-coated particles is in the range of 10:90 to 95:5 (weight of metal coating layer:weight of titanium oxide).

According to Configuration 7 of the present invention, the metal-coated particles attain appropriate electrical conductivity by virtue of the weight ratio of the titanium oxide to the metal coating layer in the metal-coated particles being in the specified range.

(Configuration 8)

Configuration 8 of the present invention is the conductive paste of any of Configurations 1 to 7, wherein (B) the resin is a thermoplastic resin and/or a thermosetting resin.

By virtue of (B) the resin being a thermoplastic resin and/or a thermosetting resin, the conductive paste according to Configuration 8 of the present invention can form a wiring of an electrical circuit and/or an electronic circuit on a workpiece for forming a wiring of an electrical circuit and/or an electronic circuit without damaging the workpiece by heating at an excessively high temperature.

(Configuration 9)

Configuration 9 of the present invention is the conductive paste of any of Configurations 1 to 8, wherein (B) the resin is a thermoplastic resin, the thermoplastic resin comprises at least one resin selected from the group consisting of polyurethane resins, polystyrene resins, acrylic resins, polycarbonate resins, polyamide resins, polyamideimide resins and thermoplastic elastomers, the glass transition temperature of the thermoplastic resin is not more than 25° C., and the thermoplastic resin is a liquid or a solution in an organic solvent.

Even when a workpiece for forming a wiring of an electrical circuit and/or an electronic circuit is made of a stretchable material, the conductive paste according to Configuration 9 of the present invention can form a wiring of an electrical circuit and/or an electronic circuit that can follow the expansion and contraction of the workpiece. Thus, a wiring of an electrical circuit and/or an electronic circuit that has a low possibility of disconnection can be formed on such a workpiece.

(Configuration 10)

Configuration 10 of the present invention is the conductive paste of any of configurations 1 to 8, wherein (B) the resin is a thermosetting resin, and the thermosetting resin comprises at least one resin selected from the group consisting of urethane resins, unsaturated polyester resins, epoxy resins and cyanate resins.

Even when a workpiece for forming a wiring of an electrical circuit and/or an electronic circuit is made of a stretchable material, the conductive paste according to Configuration 10 of the present invention, by virtue of its containing the specified resin (B), can reliably form a wiring of an electrical circuit and/or an electronic circuit that can follow the expansion and contraction of the workpiece. Thus, a wiring of an electrical circuit and/or an electronic circuit that has a low possibility of disconnection can be reliably formed on such a workpiece.

(Configuration 11)

Configuration 11 of the present invention is a cured product of the conductive paste of any of Configurations 1 to 10.

A wiring of an electrical circuit and/or an electronic circuit having a low possibility of disconnection can be obtained on the surface of a stretchable and/or flexible substrate, by applying the conductive paste of the present invention using a method such as screen printing to form a shape of a wiring of an electrical circuit and/or an electronic circuit, and curing it.

(Configuration 12)

Configuration 12 of the present invention is a conductive pattern comprising the conductive paste of any of Configurations 1 to 10.

A wiring with a low possibility of disconnection can be obtained, by using a conductive pattern of the present invention for forming a wiring of an electrical circuit and/or an electronic circuit on a surface of a stretchable and/or flexible substrate, and curing it.

(Configuration 13)

Configuration 13 of the present invention is a garment comprising the cured product of the conductive paste of Configuration 11, or the conductive pattern of Configuration 12.

By the use of the conductive paste of the present invention, a cured product of the conductive paste, or a wiring serving as a conductive film or a conductive pattern may be formed on a stretchable and/or flexible garment.

(Configuration 14)

Configuration 14 of the present invention is a stretchable paste comprising the conductive paste of any of Configurations 1 to 10.

The conductive paste of the present invention is a stretchable paste that can be suitably used to form a wiring of an electrical circuit and/or an electronic circuit that has a low possibility of disconnection even when stretched.

The conductive pastes provided according to the present invention can form a wiring of an electrical circuit and/or an electronic circuit having a low possibility of disconnection. Specifically, the conductive pastes provided according to the present invention can form a wiring of an electrical circuit and/or an electronic circuit having a low possibility of disconnection and a relatively small change in electric resistance, on a surface of a flexible and/or a stretchable material.

Further, the cured products and the conductive patterns provided according to the present invention can be used as wirings of electrical circuits and/or electronic circuits having a low possibility of disconnection. Further, the garments provided according to the present invention include a wiring of an electrical circuit and/or an electronic circuit that has a low possibility of disconnection.

Furthermore, the stretchable pastes provided according to the present invention can be used to form stretchable electrodes in electrical components and electronic components.

### BRIEF DESCRIPTION OF THE DRAWINGS

FIG. 1 is a scanning electron micrograph (magnification: ×10,000) of metal-coated particles of Reference Example 1.

FIG. 2 is a scanning electron micrograph (magnification: ×5,000) of metal-coated particles of Reference Example 1.

FIG. 3 is a scanning electron micrograph (magnification: ×10,000) of TiO₂ particles used in the production of metal-coated particles of Reference Example 1.

FIG. 4 is a scanning electron micrograph (magnification: ×5,000) of TiO₂ particles used in the production of metal-coated particles of Reference Example 1.

FIG. 5 is a schematic view illustrating the particle length L and the particle shorter diameter D of a metal-coated particle contained in a conductive paste of the present invention.

FIG. 6 is a set of schematic views of an electrode formed from a conductive paste of the present invention including a plurality of metal-coated particles on a flexible and/or stretchable material, wherein FIG. 6(a) illustrates adjacent metal-coated particles being in contact with one another, and FIG. 6(b) illustrates the ability of the metal-coated particles to maintain contact with adjacent particles even when the material is bent and/or stretched.

FIG. 7 is a set of schematic views of an electrode including a plurality of conventional spherical conductive particles, formed on a flexible and/or stretchable material, wherein FIG. 7(a) illustrates adjacent conductive particles being in contact with one another, and FIG. 7(b) illustrates the conductive particles losing contact with adjacent particles when the material is bent and/or stretched.

### MODE FOR CARRYING OUT THE INVENTION

The present invention is a conductive paste including metal-coated particles (A) and a resin (B). The metal-coated particle contained in the conductive paste of the present invention (sometimes written simply as the “metal-coated particles”) have a metal coating layer on the surface a titanium oxide. The titanium oxide that is a material for the metal-coated particles has a columnar shape having a particle length and a particle shorter diameter, and the particle length of the titanium oxide is longer than the particle shorter diameter. The metal-coated particles have a columnar shape having a particle length and a particle shorter diameter. The particle length of the metal-coated particles is longer than the particle shorter diameter.

In the present specification, the term “particle length” means the longest distance (the maximum dimension) between any two points on the surface of a particle. When a powder including a large number of metal-coated particles is photographed by electron micrograph (a SEM image), the particle lengths may be approximated as the longest distances (the maximum dimensions) between any two points on the contours of the respective particles in the SEM image. Thus, the particle length of metal-coated particles may be obtained by capturing an electron micrograph (a SEM image) of a powder including a large number of metal-coated particles, measuring the maximum dimensions of the contours of the respective particles projected in the SEM image, and calculating the average of the maximum dimensions. Alternatively, the maximum dimensions of the contours of the respective particles may be measured by analyzing the contours of the respective particles projected in the SEM image using a known image processing technique.

In the present specification, the term “particle shorter diameter” means the longest distance (the maximum dimension) between any two points on the contour of a cross-section having the largest cross-sectional area larger than any other cross-sections throughout a particle, the cross-sectional area being perpendicular to the straight line connecting the two points indicating the particle length. When a powder including a large number of metal-coated particles is photographed by electron micrograph (a SEM image), the particle shorter diameter of each particle may be approximated as the length of the longest line segment within the contour of the particle which is longer than any other line segments of straight lines perpendicular to the straight line connecting the two points indicating the particle length. Thus, the particle shorter diameter of metal-coated particles may be obtained by capturing an electron micrograph (a SEM image) of a powder including a large number of metal-coated particles, measuring the length of the longest line segment within the contour of each particle projected in the SEM image which is longer than any other line segments of straight lines perpendicular to the straight line connecting the two points indicating the particle length, and calculating the average of such maximum lengths. Alternatively, the particle shorter diameters may be measured by analyzing the contours of the respective particles projected in the SEM image using a known image processing technique.

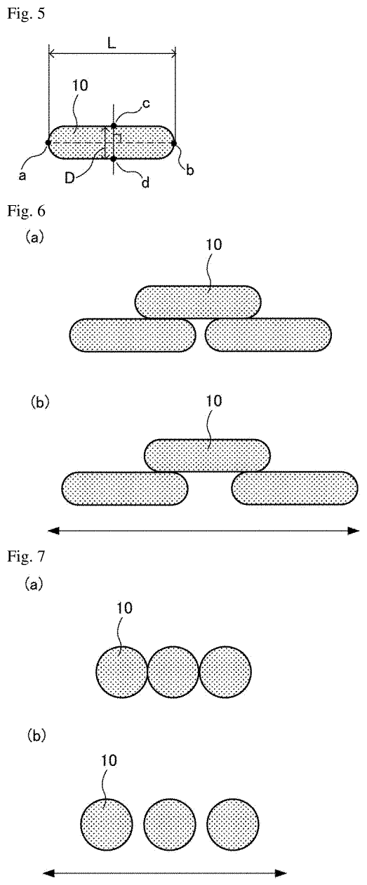

The measurement of the particle length L and particle shorter diameter D of a metal-coated particle 10 from a SEM image will be described with reference to the schematic view in FIG. 5. The particle length L is the longest distance between any two points on the contour of the metal-coated particle 10 in the SEM image (in this case, the distance L between point “a” and point “b”). Further, the particle shorter diameter D is the length of the longest line segment (the length D of the line segment connecting point “c” and point “d”) within the contour of the particle which is longer than any other line segments of straight lines (for example, the straight line passing through point “c” and point “d”) perpendicular to the straight line connecting the two points indicating the particle length L (point “a” and point “b”). The particle length and particle shorter diameter of metal-coated particles may be obtained by measuring the particle lengths L and particle shorter diameters D of the respective particles in the SEM image, and calculating the average of the particle lengths L and the average of the particle shorter diameters D. Incidentally, the magnification factor of the SEM image may be selected appropriately so that the entirety of a predetermined number of metal-coated particles to be measured will be captured in the image. The predetermined number of particles to be measured for the calculation of the average values is preferably 5 or more, preferably in the range of 10 to 100, and more preferably 20 to 50.

In the present specification, the term “columnar shape” indicates a shape in which the particle length is longer than the particle shorter diameter.

In general, conductive particles contained in a conductive paste have a spherical or flaky shape (see FIG. 7(a)). When conductive particles with such a shape are applied to the surface of a flexible and/or stretchable material to form a wiring of an electrical circuit and/or an electronic circuit, adjacent conductive particles sometimes lose their contact due to the bending and/or the stretching of the material (see FIG. 7(b)). In this case, electrical contact is also interrupted to cause disconnection. In contrast, as illustrated in FIG. 6(a), conductive particles having a predetermined columnar shape (the metal-coated particles of the present invention) can be in contact with one another while sliding on the lateral portions of the long columnar shapes of adjacent conductive particles. Thus, as illustrated in FIG. 6(b), the conductive particles can maintain contact with adjacent particles even if the material is bent and/or stretched to a certain degree. In this manner, the use of columnar conductive particles lowers the possibility of disconnection.

Because the shape of conventional conductive particles is usually spherical or flaky, there is a high risk of disconnection when a wiring of an electrical circuit and/or an electronic circuit is formed from a conductive paste containing such conductive particles on a surface of a flexible and/or a stretchable material. However, producing columnar conductive particles is not easy.

The inventors of the present invention have found that conductive particles having a columnar shape can be obtained by providing a particulate insulating substance, specifically, titanium oxide particles, and coating the surface thereof with a conductive metal. Titanium oxide particles with a predetermined columnar shape can be produced relatively easily. Titanium oxide (TiO₂) particles are thus suited as the columnar conductive particles. Incidentally, the metal-coated particles contained in the conductive paste of the present invention compare unfavorably in conductivity to particles of a metal itself. However, metal particles such as silver exhibiting high conductivity are generally more expensive than the metal-coated particles contained in the conductive paste of the present invention. Further, it is not easy to produce metal particles with a predetermined microscopic columnar structure. Thus, the metal-coated particles contained in the conductive paste of the present invention are suited for forming desired conductive wirings and the like at low cost. Further, titanium oxide is highly stable, and thus wirings and the like having a long service life can be obtained by using the conductive paste of the invention containing the specified metal-coated particles.

When an alkaline salt such as, for example, potassium titanate is used as the insulating substance, there is a risk that alkaline salt impurities may adversely affect electronic components. The use of titanium oxide as the insulating substance avoids such adverse effects and allows electrodes to be formed without adversely affecting electronic components. Further, it is relatively easy to obtain titanium oxide as particles with a predetermined columnar shape.

The metal-coated particles contained in the conductive paste of the present invention have specific columnar titanium oxide as the cores. The use of such particles makes it possible to obtain a conductive paste capable of forming a wiring of an electrical circuit and/or an electronic circuit having a low possibility of disconnection. Specifically, the use of the metal-coated particles allows for the obtaining of a conductive paste capable of forming a wiring of an electrical circuit and/or an electronic circuit having a low possibility of disconnection and a relatively small change in electric resistance, on a surface of a flexible and/or a stretchable material. Thus, the conductive paste containing the specified metal-coated particles can form a wiring of an electrical circuit and/or an electronic circuit which will have a relatively small change in electric resistance of the wiring and will have a low possibility of disconnection in the circuit even when the wiring is formed on a flexible and/or stretchable material.

In the metal-coated particles contained in the conductive paste of the present invention, the particle length of the metal-coated particles is preferably 1.5 to 30 μm, more preferably 1.8 to 15 μm, and still more preferably 2 to 6 μm. This specified particle length ensures that when the conductive paste containing such metal-coated particles is applied to form a wiring of an electrical circuit and/or an electronic circuit on a predetermined material, the conductive particles will have a reduced possibility of losing contact with adjacent particles by the bending and/or the stretching of the predetermined material. Thus, the conductive paste containing the metal-coated particles with the specified particle length can form a wiring of an electrical circuit and/or an electronic circuit having a low possibility of disconnection, on a surface of a flexible and/or a stretchable material.

In the metal-coated particles contained in the conductive paste of the present invention, the particle shorter diameter of the metal-coated particles is preferably 0.1 to 10 μm, more preferably 0.15 to 5 μm, and still more preferably 0.2 to 0.3 μm. This specified particle shorter diameter ensures that when the conductive paste containing such metal-coated particles is applied to form a wiring of an electrical circuit and/or an electronic circuit on a predetermined material, the conductive particles will have a still reduced possibility of losing contact with adjacent particles by the bending and/or the stretching of the predetermined material. Thus, the conductive paste containing the metal-coated particles with the specified particle length and the specified particle shorter diameter can more reliably form a wiring of an electrical circuit and/or an electronic circuit having a low possibility of disconnection, on a surface of a flexible and/or a stretchable material.

In the conductive paste of the present invention, the specific surface area of the metal-coated particles is preferably 0.2 to 20 m²/g, more preferably 0.3 to 15 m²/g, still more preferably 0.4 to 5 m²/g, and particularly preferably 0.5 to 3 m²/g. When the specific surface area of the metal-coated particles is in the specified range, the metal-coated particles contained in the conductive paste are of an appropriate size (dimensions) for forming a wiring of an electrical circuit and/or an electronic circuit. Incidentally, the dimensions of titanium oxide that is the raw material for the metal-coated particles are smaller than the dimensions of the metal-coated particles by the amount of the metal coating layer.

In the conductive paste of the present invention, the aspect ratio of the longer diameter to the shorter diameter of the metal-coated particles is preferably 3 to 300, more preferably 10 to 150, and still more preferably 15 to 20. A wiring of an electrical circuit and/or an electronic circuit having a low possibility of disconnection on a surface of a flexible and/or a stretchable material can be more reliably formed by using the metal-coated particles having the specified aspect ratio.

In the metal-coated particles contained in the conductive paste of the present invention, the particle length of titanium oxide as the raw material may be selected appropriately so that the metal-coated particles will attain the dimension described hereinabove. Specifically, the particle length of titanium oxide as the raw material may be 1 to 25 μm, preferably 1 to 10 μm, more preferably 1.5 to 6.0 μm, and still more preferably 1.5 to 5.2 μm. By controlling the particle length of titanium oxide in the specified range, the metal-coated particles contained in the conductive paste that is for forming a wiring of an electrical circuit and/or an electronic circuit having a low possibility of disconnection, can be obtained.

In the metal-coated particles contained in the conductive paste of the present invention, the particle shorter diameter of titanium oxide as the raw material may be selected appropriately so that the metal-coated particles will attain the dimension described hereinabove. Specifically, the particle shorter diameter of titanium oxide as the raw material may be 0.05 to 8 μm, preferably 0.05 to 1 μm, and more preferably 0.1 to 0.3 μm. By controlling the particle shorter diameter of titanium oxide in the specified range, a wiring of an electrical circuit and/or an electronic circuit having a low possibility of disconnection can be formed. Further, the use of titanium oxide satisfying a combination of the above particle length and the above particle shorter diameter allows for the obtaining of metal-coated particles for a conductive paste that can form a wiring of an electrical circuit and/or an electronic circuit having a low possibility of disconnection.

In the metal-coated particles contained in the conductive paste of the present invention, the specific surface area of titanium oxide as the raw material is preferably 2 to 20 m²/g, more preferably 3 to 15 m²/g, still more preferably 5 to 10 m²/g, and particularly preferably 5 to 7 m²/g. When the specific surface area of titanium oxide is in the specified range, the metal-coated particles are appropriate dimensions for the conductive paste to form a wiring of an electrical circuit and/or an electronic circuit. Incidentally, the dimensions of the metal-coated particles are larger than the dimensions of the metal-coated particles by the amount of the metal coating layer.

In the metal-coated particles contained in the conductive paste of the present invention, the material of the metal coating layer preferably includes at least one selected from the group consisting of Ag, Au, Cu, Ni, Pd, Pt, Sn and Pb. When the metal coating layer includes the specified metal, a wiring of an electrical circuit and/or an electronic circuit that has a low electric resistance can be formed. In particular, silver (Ag) has high electrical conductivity, and thus the metal coating layer preferably includes silver and more preferably substantially consists of silver. The phrase “the metal coating layer substantially consists of silver” means that the metal coating layer consists solely of silver except inevitable impurities.

In the metal-coated particles (A) contained in the conductive paste composition of the present invention, the weight ratio of the weight of the metal coating layer to the weight of titanium oxide (weight of metal coating layer:weight of titanium oxide) is preferably in the range of 10:90 to 95:5, more preferably in the range of 20:80 to 95:5, or 10:90 to 90:10, and still more preferably in the range of 25:75 to 90:10.

When the weight ratio of titanium oxide:metal coating layer in the metal-coated particles is in the specified range, the metal-coated particles with appropriate electrical conductivity can be obtained. The weight ratio of the metal coating layer to the titanium oxide may be controlled by controlling the particle dimensions of the titanium oxide and the thickness of the metal coating layer. The weight ratio of the metal coating layer to the titanium oxide may be selected appropriately in accordance with the use application. To obtain high electrical conductivity, the weight ratio of the metal coating layer is preferably high. However, when the weight ratio of the titanium oxide serving as the cores is less than 5% by weight, it is difficult for the particles to attain the desired columnar shape by the formation of the metal coating layer. When the weight ratio of the metal coating layer to the titanium oxide in the metal-coated particles is in the specified range, the metal-coated particles with appropriate electrical conductivity can be obtained.

The surface of the metal-coated particles is preferably treated with a surface treatment agent. Fatty acids and salts thereof may be preferably used as the surface treatment agents. The treatment of the surface of the metal-coated particles with the surface treatment agent enhances the wettability with resin components and high dispersibility can be obtained.

The following provides an explanation of a method for producing the metal-coated particles contained in the conductive paste of the present invention.

First, titanium oxide (TiO₂) having the aforementioned predetermined columnar shape is provided. Titanium oxide (TiO₂) having the predetermined columnar shape which may be used in the metal-coated particles is known and may be purchased in the market. For example, acicular titanium oxide manufactured by Ishihara Sangyo Kaisha, Ltd. (FTL Series, e.g., FTL-300) may be used as the titanium oxide having the predetermined columnar shape. The crystal structure of the titanium oxide may be the rutile crystal.

Next, the titanium oxide having the predetermined columnar shape is coated with a metal. The titanium oxide may be coated with a metal by a known film-forming method such as plating, vacuum deposition or CVD. Plating (electroless plating) is preferably used as the coating method because a coating can be formed at a relatively low cost without using vacuum equipment. As an example of the coating methods, the following provides an explanation of the plating of silver on titanium oxide having the predetermined columnar shape.

First, titanium oxide having the predetermined columnar shape is subjected to sensitizing treatment. In the sensitizing treatment, specifically, titanium oxide particles are immersed in a sensitizing solution to adsorb a metal compound such as a Sn compound onto the titanium oxide particles. The sensitizing solution may be a solvent containing a Sn compound. For example, the Sn compound may be selected from, among others, tin (II) chloride (SnCl₂), stannous acetate (Sn(CH₃COCHCOCH₃)₂), stannous bromide (SnBr₂), stannous iodide (SnI₂) and stannous sulfate (SnSO₄). For example, the solvent may be selected from, among others, alcohols, aqueous alcohol solutions and dilute aqueous solutions of hydrochloric acid.

After the sensitizing treatment, the titanium oxide particles are collected by filtration, and are preferably dehydrated and washed.

Next, the sensitized titanium oxide is activated (is subjected to activating treatment). In the activating treatment, specifically, the sensitized titanium oxide particles are immersed in an activating solution to adsorb a plating catalyst onto the titanium oxide particles. Pd, Ag or Cu may be preferably used as the plating catalyst. In the case the particles are plated with silver, Ag is preferably used as the plating catalyst. When Ag is used as the plating catalyst, the activating solution may be an aqueous solution containing silver nitrate and aqueous ammonia.

After the activating treatment, the titanium oxide particles are collected by filtration, and are preferably dehydrated, washed and dried. For example, drying may be carried out at a temperature of 30 to 100° C. for about 1 to 20 hours. By performing filtration, dehydration, washing and drying, the adhesion between the titanium oxide particles and the metal coating layer may be enhanced.

Incidentally, the sensitizing treatment and the activating treatment may be repeated a plurality of times, for example, about two to five times. The plating catalyst may be adsorbed more uniformly by repeating the sensitizing treatment and the activating treatment a plurality of times.

Next, plating treatment is carried out on the sensitized and activated titanium oxide. In the plating treatment, specifically, the sensitized and activated titanium oxide particles are immersed in a plating solution, and silver is deposited on the surface of the titanium oxide particles by electroless plating to form a metal coating layer. For example, an aqueous solution containing silver nitrate and aqueous ammonia may be used as the plating solution.

In the formation of a silver metal coating layer by electroless plating, almost all of the silver contained in the plating solution may be deposited as a metal coating layer by appropriately controlling the electroless plating conditions such as the type of the plating solution (the type of a reducing agent that is added thereto), the concentration and amount of the plating solution, and the amount of time and the temperature during the electroless plating. Controlling appropriately the electroless plating conditions is a known practice. Thus, the weight ratio of the weight of the metal coating layer (silver) to the weight of the titanium oxide may be controlled by controlling the amount of silver (for example, the amount of silver nitrate) contained in the plating solution. Alternatively, the weight ratio of the weight of the metal coating layer (silver) to the weight of the titanium oxide may be controlled by measuring the metal deposition rate and adjusting the amount of time of electroless plating.

While a silver metal coating layer may be formed in the manner described hereinabove as an example, a metal coating layer of other metal may be formed by changing the type of the plating solution used in the plating treatment. Electroless plating of metals other than Ag such as Au, Cu, Ni, Pd, Pt, Sn and Pb to form metal coating layers is a known technique. In addition, electroless plating of Co, Rh, In and the like may also be performed. That is, metal-coated particles having a metal coating layer made of any of these metals may be produced using an electroless plating method.

The metal-coated particles contained in the conductive paste of the present invention may be produced as described in the above example.

Next, the conductive paste of the present invention is described. The conductive paste of the present invention is a paste containing the aforementioned metal-coated particles and a resin.

The conductive paste of the present invention includes the aforementioned metal-coated particles of the present invention as conductive particles. Further, the conductive paste of the present invention may contain additional conductive particles other than the columnar metal-coated particles of the present invention. The conductive particles other than the metal-coated particles of the present invention may be spherical and/or flaky conductive particles. In the conductive particles contained in the conductive paste of the present invention, the weight ratio of the metal-coated particles of the present invention to additional conductive particles other than the metal-coated particles of the present invention (metal-coated particles:additional conductive particles) is preferably 98:2 to 70:30, and more preferably 95:5 to 90:10. The conductive particles other than the metal-coated particles of the present invention may be made of materials similar to the metal materials used to form the metal coating layers in the metal-coated particles of the present invention.

In the conductive paste of the present invention, the resin (B) is preferably a thermoplastic resin and/or a thermosetting resin.

By virtue of the resin being a thermoplastic resin and/or a thermosetting resin, the conductive paste of the present invention can form a wiring of an electrical circuit and/or an electronic circuit on a workpiece for forming a wiring of an electrical circuit and/or an electronic circuit without damaging the workpiece by heating.

The resin contained in the conductive paste of the present invention may be selected from thermoplastic resins, thermosetting resins and/or photocuring resins. Examples of the thermoplastic resins include acrylic resins, ethyl celluloses, polyesters, polysulfones, phenoxy resins and polyimides. Some preferred thermosetting resins are amino resins such as urea resins, melamine resins and guanamine resins; epoxy resins such as bisphenol A resins, bisphenol F resins, phenol novolac resins and alicyclic resins; oxetane resins; phenol resins such as resol resins and novolac resins; and silicone-modified organic resins such as silicone epoxies and silicone polyesters. The photocuring resins may be selected from, among others, UV-curable acrylic resins and UV-curable epoxy resins. These resins may be used singly, or two or more may be used in combination.

When the resin (B) contained in the conductive paste of the present invention is a thermoplastic resin, the thermoplastic resin preferably includes at least one resin selected from the group consisting of polyurethane resins, polystyrene resins, acrylic resins, polycarbonate resins, polyamide resins, polyamideimide resins and thermoplastic elastomers. Further, the glass transition temperature of the thermoplastic resin is preferably not more than 25° C. Furthermore, the thermoplastic resin is preferably a liquid or a solution in an organic solvent.

When the resin (B) contained in the conductive paste of the present invention is a thermosetting resin, the thermosetting resin preferably includes at least one resin selected from the group consisting of urethane resins, unsaturated polyester resins, epoxy resins and cyanate resins.

Even when an electrical circuit and/or an electronic circuit wiring workpiece is made of a stretchable material, the conductive paste of the present invention, by virtue of its containing the specified resin (B), can reliably form a wiring of an electrical circuit and/or an electronic circuit that can follow the expansion and contraction of the workpiece. Thus, a wiring of an electrical circuit and/or an electronic circuit that has a low possibility of disconnection can be reliably formed on such a workpiece.

In the conductive paste of the present invention, the weight ratio of the metal-coated particles to the resin is preferably 90:10 to 70:30. When the weight ratio of the metal particles to the resin is in the above range, and the conductive paste containing the metal-coated particles is applied to a substrate to form a coating film or a wiring, the conductive film or a wiring, which is obtained by heating, can maintain the desired specific resistance. In the case the conductive paste contains additional conductive particles other than the metal-coated particles of the present invention, the weight ratio of all the conductive particles is preferably within the aforementioned range.

The conductive paste of the present invention may further include a solvent. Examples of the solvents include aromatic hydrocarbons such as toluene and xylene; ketones such as methyl ethyl ketone, methyl isobutyl ketone and cyclohexanone; esters such as ethylene glycol monomethyl ether, ethylene glycol monoethyl ether, ethylene glycol monobutyl ether, diethylene glycol monomethyl ether, diethylene glycol monoethyl ether, diethylene glycol monobutyl ether, dipropylene glycol monomethyl ether, and esters thereof such as acetates; and terpineol. The solvent is preferably added in an amount of 2 to 10 parts by mass based on the total of the metal particles and the resin taken as 100 parts by mass.

The viscosity of the conductive paste of the present invention may be adjusted to a level of viscosity suited for a specific method such as screen printing for forming coating films or wirings. The viscosity may be adjusted by appropriately controlling the amount of the solvent. Specifically, the amount of the solvent may be controlled so that the viscosity of the conductive paste will be 1 to 200 Pa·sec, preferably 2 to 150 Pa·sec, and more preferably 5 to 120 Pa·sec. The viscosity of the conductive paste may be measured at a temperature of 25° C. and a rotational speed of 10 rpm using a Brookfield viscometer (a B type viscometer).

The conductive paste of the present invention may further include at least one selected from the group consisting of inorganic pigments, organic pigments, silane coupling agents, leveling agents, thixotropic agents and antifoaming agents.

The conductive paste of the present invention may be produced by adding the aforementioned metal-coated particles of the present invention, the resin and optionally other components to a mixer such as a planetary stirrer, a dissolver, a bead mill, a crusher, a three-roll mill, a rotary mixer or a twin-screw mixer, followed by mixing of the materials. In this manner, a conductive paste may be produced which has a viscosity suited for screen printing, dipping or other desired technique for forming coating films or wirings.

The present invention pertains to a cured product obtained by curing the conductive paste of the present invention described hereinabove. A wiring of an electrical circuit and/or an electronic circuit can be formed by printing with screen printing or the like on a predetermined material and heat treatment, so as to be a predetermined conductive pattern. The conductive pattern formed above includes the conductive paste. A cured product formed from the conductive paste of the present invention can serve as a wiring of an electrical circuit and/or an electronic circuit having a low possibility of disconnection, on a surface of a flexible and/or a stretchable material.

A cured product (such as a wiring of an electrical circuit and/or an electronic circuit) may be formed from the conductive paste of the present invention by heat treatment at any temperature and under any conditions without limitation. However, it is necessary that the temperature is for sufficiently removing the solvent, and, in the case of a thermosetting resin, crosslinking the organic components. To reduce costs, the treatment is preferably performed at a low temperature and in a short time.

Specifically, the heat treatment temperature is preferably not less than 25° C. and not more than 300° C., more preferably not less than 50° C. and not more than 180° C., and still more preferably not less than 80° C. and not more than 150° C. The amount of heat treatment time is preferably 5 to 120 minutes, more preferably 10 to 60 minutes, and still more preferably 20 to 40 minutes. Curing may be accomplished at a low temperature in the case of a thermoplastic resin. From the point of view of low cost, it is preferable that a thermoplastic resin is cured in a short time. Thus, the heat treatment is more preferably performed at a temperature higher than room temperature as described above even when a thermoplastic resin is used.

The conductive paste of the present invention may constitute a garment in the form of a cured product of the conductive paste described hereinabove or a conductive pattern described hereinabove. A wiring of an electrical circuit and/or an electronic circuit is sometimes formed to impart a function to a garment. In such cases, the conductive paste of the present invention may be suitably used to form a wiring of an electrical circuit and/or an electronic circuit on a garment. The conductive paste of the present invention may be applied to a fabric as the material by screen printing or the like to form a predetermined wiring pattern, and may be thereafter heat treated to form a predetermined wiring of an electrical circuit and/or an electronic circuit.

The present invention is a stretchable paste including the conductive paste described hereinabove. The term stretchable paste means a conductive paste for forming a flexible and/or stretchable electrode. The conductive paste of the present invention may be suitably used as a stretchable paste.

### EXAMPLES

Hereinbelow, the present invention will be described in detail based on Examples. However, the scope of the present invention is not limited thereto.

<Materials and Formulations of Conductive Pastes>

Table 1 describes formulations of conductive pastes of Examples and Comparative Examples. The amounts shown in Table 1 are parts by weight based on the total weight of conductive particles and resin components taken as 100 parts by weight. The conductive pastes of Examples and Comparative Examples are conductive pastes composed of conductive particles (metal-coated particles or silver particles), resin components and a solvent (a diluting solvent). The conductive particles used in the conductive pastes of Examples are metal-coated particles. The conductive particles used in the conductive pastes of Comparative Examples are conventional silver particles.

<Metal-Coated Particles of Reference Example 1>

Silver was used as the main metal material in the metal-coated particles. For example, the metal-coated particles of Reference Example 1 may be produced as follows. In the metal-coated particles of Reference Example 1, the weight ratio of titanium oxide:metal (silver) coating layer is 50:50.

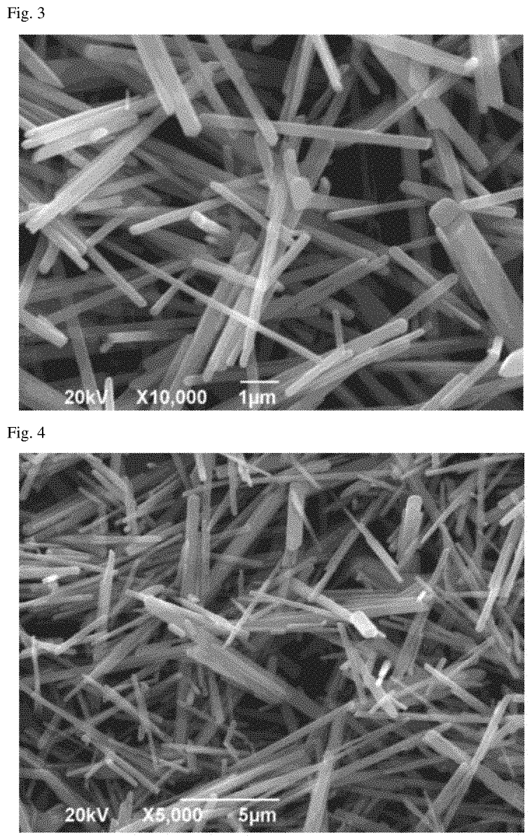

Acicular titanium oxide (FTL-300) manufactured by Ishihara Sangyo Kaisha, Ltd. was used as a titanium oxide (TiO₂) powder serving as a raw material for metal-coated particles. Incidentally, FTL-300 is a rutile TiO₂ powder having a particle length of 5.15 μm and a particle shorter diameter of 0.27 μm, and had a true specific gravity of 4.2 and a specific surface area of 5 to 7. FIGS. 3 and 4 show scanning electron micrographs of the titanium oxide powder as a raw material.

The titanium oxide was coated with the metal in the following manner First, the titanium oxide powder was subjected to sensitizing treatment. Specifically, 50 g of the titanium oxide powder was dispersed in 800 g of ion exchange water, and was sensitized for 10 minutes using a sensitizing solution containing 2.5 g of tin (II) chloride and 0.5 g of hydrochloric acid in ion exchange water (20 g). Thereafter, the titanium oxide powder was collected by filtration, dehydrated and washed.

Next, the sensitized titanium oxide powder was subjected to activating treatment. Specifically, the sensitized titanium oxide powder was dispersed in 900 g of ion exchange water, and was sensitized for 10 minutes using an activating solution containing 5 g of silver nitrate and 10 ml of aqueous ammonia (concentration: 25%) in ion exchange water (100 g). Thereafter, the titanium oxide powder was collected by filtration, dehydrated and washed. The resultant titanium oxide powder was dried at 60° C. for 12 hours.

The sensitized and activated titanium oxide powder was subjected to plating treatment (electroless plating) to form a silver metal coating layer on the surface of the titanium oxide particles. Specifically, 20 g of the treated titanium oxide powder was dispersed in 690 g of ion exchange water, and ion exchange water (50 g) containing 32 g of silver nitrate and 50 ml of aqueous ammonia (concentration: 25%) was added. Thereafter, 10 ml of sulfuric acid was added, and 200 ml of aqueous ammonia (concentration: 25%) was further added. To the solution (the plating solution) obtained as described above, an aqueous solution of 11 g of hydrazine monohydrate (50 g ion exchange water) was added over a period of 7 minutes to form a silver metal coating layer on the surface of the titanium oxide particles. Metal-coated particles were thus obtained. Here, the aqueous hydrazine monohydrate solution was added while performing stirring. After the completion of the addition of the aqueous hydrazine monohydrate solution, stirring was continuously performed for at least 15 minutes. Subsequently, the metal-coated particles were collected by filtration, dehydrated and washed. The resultant metal-coated particles were dried at 60° C. for 12 hours. Metal-coated particles of Reference Example 1 having a weight ratio of titanium oxide:metal (silver) coating layer of 50:50 may be produced in the manner described above.

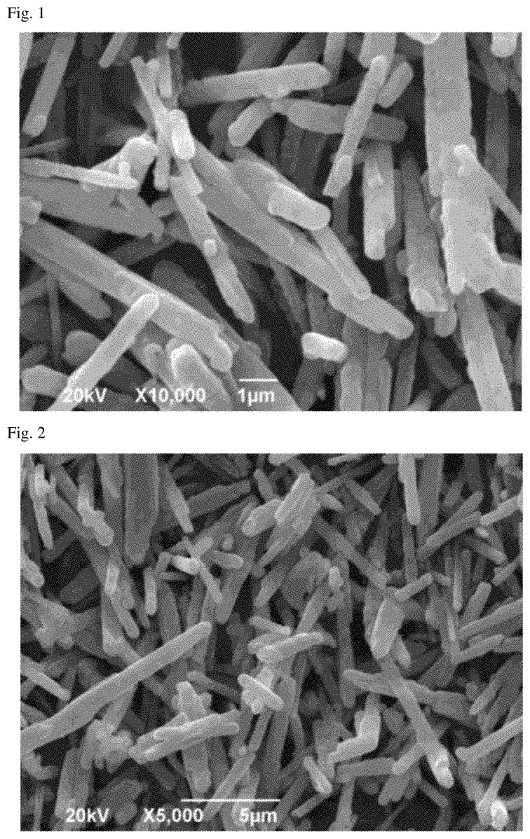

FIGS. 1 and 2 show scanning electron micrographs of the metal-coated particles of Reference Example 1 produced in the manner described above. In the metal-coated particles of Reference Example 1, the weight ratio of titanium oxide to the metal coating layer is 50:50. The BET specific surface area was measured of the titanium oxide powder and the metal-coated particles. The BET specific surface area of the titanium oxide powder was 2.80 m²/g, and the BET specific surface area of the metal-coated particles was 1.83 m²/g. The average values of particle length and particle shorter diameter of the metal-coated particles were measured. The fiber length was 5.25 μm and the fiber diameter was 0.37 μm. From these results, it has been shown that metal-coated particles having a predetermined columnar shape can be obtained by the production method described above.

The metal-coated particles shown in FIGS. 1 and 2 have a long columnar shape. When these metal-coated particles are applied to form a wiring and/or electrodes on the surface of a stretchable material, the metal-coated particles are in contact with one another on their lateral faces and thus can maintain contact with adjacent metal-coated particles even when the material is stretched, thereby reducing the possibility of disconnection. Further, these long columnar metal-coated particles are entangled with one another and are unlikely to be disconnected even in the case a wiring and/or electrodes are formed from the metal-coated particles on the surface of a flexible material.

<Metal-Coated Particles A>

Metal-coated particles A were used for conductive pastes of Examples 1, 2 and 4. In the particles, the weight ratio of the weight of the metal coating layer (silver) to the weight of titanium oxide (weight of metal coating layer:weight of titanium oxide) is 90:10. The metal-coated particles A were produced in the same manner as the metal-coated particles of Reference Example 1 described above. However, the amount of the sensitized and activated titanium oxide powder used in the plating treatment (electroless plating) was changed to 2.22 g to be the weight ratio of titanium oxide:metal coating layer (silver) in the metal-coated particles A to 90:10. The metal-coated particles A had an average particle size (D50) of 22.6 μm and a specific surface area of 0.88 m²/g.

<Metal-Coated Particles B>

Metal-coated particles B were used for a conductive paste of Example 3. In the particles, the weight ratio of the weight of the metal coating layer (silver) to the weight of titanium oxide (weight of metal coating layer:weight of titanium oxide) is 25:75. The metal-coated particles B were produced in the same manner as the metal-coated particles of Reference Example 1 described above. However, the amount of the sensitized and activated titanium oxide powder used in the plating treatment (electroless plating) was changed to 6.67 g to be the weight ratio of titanium oxide:metal coating layer (silver) in the metal-coated particles B to 25:75. The metal-coated particles B had an average particle size (D50) of 16.0 μm and a specific surface area of 0.95 m²/g.

<Silver Particles>

Silver particles were used as conductive particles in conductive pastes of Comparative Examples 1 to 3. The silver particles used in Comparative Examples are described below. Table 1 describes the amounts of the silver particles added. The amounts shown in Table 1 are parts by weight based on the total weight of the conductive particles and resin components taken as 100 parts by weight.

Silver particles A: AA-40719 (manufactured by Metalor). The particle shape is scaly. The average particle size (D50) is 2.1 μm, and the specific surface area is 1.11 m²/g.

Silver particles B: SF7A (manufactured by Ames Goldsmith). The particle shape is scaly. The average particle size (D50) is 1.7 μm, and the specific surface area is 0.87 m²/g.

Silver particles C: SFR-AG5 (manufactured by NIPPON ATOMIZED METAL POWDERS, INC.). The particle shape is spherical. The average particle size (D50) is 4.8 μm, and the specific surface area is 0.23 m²/g.

<Resin Components>

Table 1 describes the amounts of resin components used in Examples and Comparative Examples. The amounts shown in Table 1 are parts by weight based on the total weight of the conductive particles and the resin components taken as 100 parts by weight. The resin component used in Examples 1 to 3 and Comparative Examples 1 to 3 is a polyurethane resin (Desmocoll 406 manufactured by Covestro). The resin component was dissolved into a solvent described later to give a raw material for a conductive paste.

The resin components used in Example 4 are as follows. The amount of the isocyanate shown in Table 1 is the amount of the isocyanate excluding the amount of a solvent. 7.2 Parts by weight of the isocyanate was used as a solution in 5.3 parts by weight of an organic solvent (butyl butanol acetate). The polyol and the aluminum chelate, which were used, were liquid. It is probable that the resin components used in Example 4 were polymerized into polyurethane during the thermal curing of the conductive paste. Thus, the resin components used in Example 4 are thermosetting resin components.

Isocyanate: DURANATE MF-K60B (manufactured by Asahi Kasei Corporation)

Polyol: DURANOL T5650E (manufactured by Asahi Kasei Corporation)

Aluminum chelate: PLENACT AL-M (manufactured by Ajinomoto Fine-Techno Co., Inc.)

<Solvent>

The resin components in Examples and Comparative Examples were used as resin solutions by being dissolved in the amounts described in Table 1 of a solvent (dipropylene glycol monomethyl ether, manufactured by Wako Pure Chemical Industries, Ltd.). The amounts shown in Table 1 are parts by weight based on the total weight of the conductive particles and the resin components taken as 100 parts by weight. The amounts of the solvent in Example 2 and Comparative Examples 1 and 2 were determined as shown in Table 1 as a result of adjustment in order to be a similar printing condition as the screen printing in Example 1. Specifically, the amounts of the solvent in Example 2 and Comparative Examples 1 and 2 were adjusted so that the viscosity would be about the same as that of the conductive paste of Example 1. The silver particles C used in Comparative Example 4 were spherical particles and would be sediment and be separated if viscosity of the conductive paste was low. Thus, the amount of the solvent in Comparative Example 4 was adjusted so that the viscosity was such that the silver particles would not be sediment and be separated.

<Preparation of Conductive Pastes>

The predetermined materials were mixed together in the proportions shown in Table 1 with a planetary mixer and were further dispersed with a three-roll mill into pastes. Conductive pastes were thus prepared.

<Method for Measuring Viscosity>

The viscosity of the conductive pastes of Examples and Comparative Examples was measured at a temperature of 25° C. using a Brookfield viscometer (a B type viscometer). The viscosity was measured at a rotational speed of 10 rpm for each of the conductive pastes of Examples and Comparative Examples.

<Method for Measuring Specific Resistance>

The conductive paste (the resin composition) of Example or Comparative Example was applied onto an alumina substrate using a screen printing machine to print a wiring pattern having a width of 1 mm and a length of 71 mm for specific resistance measurement. The pattern was thermally cured in a constant-temperature dryer at 120° C. for 30 minutes. The cured wiring pattern (simply written as the “wiring pattern”) was analyzed with a surface texture and contour measuring instrument (model: SURFCOM 1500SD-2) manufactured by TOKYO SEIMITSU CO., LTD. to measure the film thickness. The electric resistance of the wiring pattern was measured using a digital multimeter (model: 2001) manufactured by TFF Keithley Instruments. The specific resistance was calculated from the value of electric resistance and the dimensions of the wiring pattern. Table 2 describes the specific resistances of Examples and Comparative Examples.

<Method for Measuring Wiring Resistance>

Next, the conductive paste (the resin composition) of Example or Comparative Example was applied onto a 40 mm×140 mm polyurethane sheet using a screen printing machine to print a wiring pattern having a width of 1 mm and a length of 90 mm for wiring resistance measurement (simply written as “wiring pattern”). The pattern was thermally cured in a constant-temperature dryer at 120° C. for 30 minutes. The cured wiring pattern (simply written as the “wiring pattern”) was analyzed with a digital multimeter (model: 2001) manufactured by TFF Keithley Instruments to measure the electric resistance (simply written as “wiring resistance”). Table 2 describes the wiring resistances (the initial wiring resistances) of Examples and Comparative Examples before application of stretching stress.

Next, a stretching stress was applied five times in the longitudinal direction of the urethane sheet on which the wiring pattern was formed, and the wiring resistance was measured. Specifically, the urethane sheet, on which the wiring pattern was formed, was stretched by the application of a tensile force in the longitudinal direction to a predetermined length, and was then held at the predetermined length for 15 minutes. Thereafter, the tensile force for stretching was released. After the urethane sheet (and the wiring pattern) contracted as a result of the release of the tensile force, the urethane sheet was stretched again by the application of a tensile force to the predetermined length and was held as such for 15 minutes. This cycle of stretching and holding of the urethane sheet, and releasing of the tensile force was repeated five times, and thereafter the wiring resistance was measured. The urethane sheet was stretched until the wiring pattern was stretched in the longitudinal direction to 1.3 times of the length without stretching (in the initial state).

Table 2 describes the results of measurement of the wiring resistance after 5 cycles of stretching stress on the urethane sheet on which bearing the wiring pattern was formed. In Table 1, “Stretched” indicates the wiring resistance of the wiring pattern in the stretched state after being held in the stretched condition for 15 minutes in the 5th cycle. In Table 1, “Released” indicates the wiring resistance of the wiring pattern after the wiring pattern contracted as a result of the release of the stretching tensile force after the wiring pattern had been held stretched for 15 minutes in the 5th cycle. Further, “Ratio of resistance change” indicates the ratio of the wiring resistance after 5 cycles to the initial wiring resistance (wiring resistance after 5 cycles/initial wiring resistance).

<Measurement Results>

As is clear from Table 2, the wiring patterns of Examples 1 to 4 manufactured using the conductive pastes of the present invention had as low a wiring resistance as 159.2Ω (Example 3) or less in the stretched state, and as low a wiring resistance as 88.4Ω (Example 3) or less after the release of stretching stress after 5 cycles of stretching stress thereon. Further, the ratio to the initial wiring resistance in Examples 1 to 4 was as low as 9.6 (Example 2) or less in the stretched state and as low as 4.6 (Example 2) or less after the release of stretching stress. In contrast, the wiring patterns of Comparative Examples 1 and 2 which included conventional silver particles had as high a wiring resistance as 509.8Ω (Comparative Example 2) or above in the stretched state, and as high a wiring resistance as 115.4Ω (Comparative Example 2) or above after the release of stretching stress after 5 cycles of stretching stress thereon. Further, the ratio to the initial wiring resistance in Comparative Examples 1 and 2 was as high as 42.1 (Comparative Example 1) or above in the stretched state and as high as 10.6 (Comparative Example 2) or above after the release of stretching stress. The wiring pattern formed from the conductive paste of Comparative Example 3 did not show electrical conductivity in the initial state, and therefore could not be measured for the specific resistance and the initial wiring resistance. Thus, the corresponding sections for Comparative Example 3 in the table show “N/A”.

From the results shown above, it can be said that the conductive paste of the present invention can form a wiring of an electrical circuit and/or an electronic circuit having a low possibility of disconnection and a relatively small change in electric resistance, on a surface of a flexible and/or a stretchable material.

TABLE 1

| (Parts by weight based | | | | | | | | |
|---|---|---|---|---|---|---|---|---|
| on total weight of conductive | | | | | | | | |
| particles and resin components | | | | | | Comp. | Comp. | Comp. |
| taken as 100 parts by weight) | | Ex. 1 | Ex. 2 | Ex. 3 | Ex. 4 | Ex. 1 | Ex. 2 | Ex. 3 |
| Conductive | Metal-coated | 95 | 90 | | 90 | | | |
| particles | particles A | | | | | | | |
| | Metal-coated | | | 80 | | | | |
| | particles B | | | | | | | |
| | Silver particles | | | | | 90 | | |
| | A | | | | | | | |
| | Silver particles | | | | | | 90 | |
| | B | | | | | | | |
| | Silver particles | | | | | | | 90 |
| | C | | | | | | | |
| Resin | Polyurethane | 5 | 10 | 20 | | 10 | 10 | 10 |
| components | resin | | | | | | | |
| | Isocyanate | | | | 7.2 | | | |
| | Polyol | | | | 2.6 | | | |
| | Aluminum | | | | 0.2 | | | |
| | chelate | | | | | | | |

| | | | | | | | |
|---|---|---|---|---|---|---|---|
| Solvent (dipropylene | 30 | 48 | 68 | 30 | 37.0 | 39.0 | 30 |
| glycol monomethyl ether) | | | | | | | |

TABLE 2

| | | | | | | | Comp. | Comp. | Comp. |
|---|---|---|---|---|---|---|---|---|---|
| | | | Ex. 1 | Ex. 2 | Ex. 3 | Ex. 4 | Ex. 1 | Ex. 2 | Ex. 3 |
| Viscosity (10 rpm) (Pa · sec) | | | 32 | 31 | 115 | 5 | 32 | 25 | 149 |
| Wiring specific resistance | | | 67.1 | 103.9 | 136.4 | 99.8 | 38.7 | 33.1 | N/A |
| (μΩ · cm) | | | | | | | | | |
| Wiring | Initial wiring resistance | | 11.5 | 17.8 | 20.5 | 18.6 | 16.4 | 10.9 | N/A |
| resistance | (Ω) | | | | | | | | |
| | Wiring | Stretched | 102.2 | 170.7 | 159.2 | 95.1 | 692.3 | 509.8 | — |
| | resistance (Ω) | Released | 44.4 | 82.5 | 88.4 | 32.3 | 188.4 | 115.4 | — |
| | (after 5 cycles) | | | | | | | | |
| | Ratio of | Stretched | 8.9 | 9.6 | 7.8 | 5.1 | 42.1 | 46.9 | — |
| | resistance | Released | 3.9 | 4.6 | 4.3 | 1.7 | 11.5 | 10.6 | — |
| | change | | | | | | | | |
| | (after 5 cycles) | | | | | | | | |

### DESCRIPTION OF THE NUMERAL REFERENCES

10 METAL-COATED PARTICLE

L PARTICLE LENGTH OF METAL-COATED PARTICLE

D PARTICLE SHORTER DIAMETER OF METAL-COATED PARTICLE

1. A conductive paste comprising:
(A) metal-coated particles having a metal coating layer on a surface of titanium oxide; and
(B) a resin,
wherein:
the titanium oxide has a columnar shape having a particle length and a particle shorter diameter, the particle length of the titanium oxide being longer than the particle shorter diameter, and
the metal-coated particles have a columnar shape having a particle length and a particle shorter diameter, the particle length of the metal-coated particles being longer than the particle shorter diameter.

2. The conductive paste according to claim 1, wherein the metal coating layer of (A) the metal-coated particles comprises at least one selected from the group consisting of Ag, Au, Cu, Ni, Pd, Pt, Sn and Pb.

3. The conductive paste according to claim 1, wherein the particle length of (A) the metal-coated particles is 1.5 to 30 ∥m.

4. The conductive paste according to claim 1, wherein the particle shorter diameter of (A) the metal-coated particles is 0.1 to 10 μm.

5. The conductive paste according to claim 1, wherein the specific surface area of (A) the metal-coated particles is 0.2 to 20 m²/g.

6. The conductive paste according to claim 1, wherein the ratio of the particle length to the particle shorter diameter (particle length/particle shorter diameter) of (A) the metal-coated particles is 3 to 300.

7. The conductive paste according to claim 1, wherein the weight ratio of the weight of the metal coating layer to the weight of the titanium oxide in (A) the metal-coated particles is in the range of 10:90 to 95:5 (weight of metal coating layer:weight of titanium oxide).

8. The conductive paste according to claim 1, wherein (B) the resin is at least one of a thermoplastic resin and a thermosetting resin.

9. The conductive paste according to claim 1, wherein:
(B) the resin is a thermoplastic resin,
the thermoplastic resin comprises at least one resin selected from the group consisting of polyurethane resins, polystyrene resins, acrylic resins, polycarbonate resins, polyamide resins, polyamideimide resins and thermoplastic elastomers,
the glass transition temperature of the thermoplastic resin is not more than 25° C., and
the thermoplastic resin is a liquid or a solution in an organic solvent.

10. The conductive paste according to claim 1, wherein (B) the resin is a thermosetting resin, and the thermosetting resin comprises at least one resin selected from the group consisting of urethane resins, unsaturated polyester resins, epoxy resins and cyanate resins.

11. A cured product of the conductive paste according to claim 1.

12. A conductive pattern comprising the conductive paste according to claim 1.

13. A garment comprising the cured product of the conductive paste according to claim 11.

14. A stretchable paste comprising the conductive paste according to claim 1.

15. A garment comprising the conductive pattern according to claim 12.
